(19) United States
(12) Patent Application Publication
(10) Pub. No.: US 2024/0429789 A1
(43) Pub. Date: Dec. 26, 2024

(54) A METHOD FOR ELECTRIC LEAKAGE SAFETY OF AN ELECTRIC MOTOR, AND A PROTECTION SYSTEM

(71) Applicant: Zparq AB, Stockholm (SE)

(72) Inventors: Mikael SUNDBERG, Tyresö (SE); Jonas GENCHEL, Enskede (SE)

(21) Appl. No.: 18/693,354

(22) PCT Filed: Sep. 20, 2022
(86) PCT No.: PCT/SE2022/050826

§ 371 Date: Mar. 19, 2024

(30) Foreign Application Priority Data
Sep. 21, 2021 (SE) 2151150-6

(51) Int. Cl. H02K 11/33; G01R 31/00; G01R 31/34; G01R 31/52; H02H 3/16; H02K 5/132; H02K 11/26

(52) U.S. Cl. CPC H02K 11/33; G01R 31/008; G01R 31/343; G01R 31/52; H02H 3/16; H02K 5/132; H02K 11/26; H02K 2213/06

(57) ABSTRACT

The present invention relates a method (200) for electric leakage safety of an electric motor (101) immersed in water and being connected to a power supply (102), wherein the method (200) uses a protection system (103). The protection system (103) comprises a sensor arrangement (104) and a control unit (105) operable to receive a sensor signal SS from the sensor arrangement. The control unit (105) is further operable to control the power supply (102) connected to the electric motor (101) by means of a control signal CS. The method (200) comprises connecting (201) the power supply to the electric motor, measuring 202 with the sensor arrangement the electrical potential. and disconnecting (203) the power supply from the immersed electric motor by means of said control signal CS when the electric potential is above. or equal to. a threshold value indicative of an electric leakage. The present invention also relates to a protection system.

### TECHNICAL FIELD

The present disclosure relates to a method for electric leakage safety of an electric motor. More particular, the invention relates to electric leakage safety of an immersed electric motor. The present disclosure also relates to an electric leakage protection system for an immersed electric motor.

### BACKGROUND

Electronics are typically not suited for immersible applications; even less if the liquid the motor is immersed in is conductive, such as water. This is dangerous both for the surrounding and for the electronics as such. Especially for medium to high voltage electronics. There are however numerous applications for electronics close to water, for example electrical motors powering a boat or similar. A typical solution would be to keep the motor protected above the surface, directing the torque of the motor to an immersed propeller or similar. This would protect the motor and the surroundings. However, this results in a complex construction that both demands means for directing the torque and cooling of the motor.

Electrical motors provide numerous benefits, both to performance and to the environment. However, immersing an electrical motor proves to be a challenge since if the housing of the electrical motor is leaking the internal electronics of the motor becomes short-circuited and results in an increased risk of damage. Various solutions to detect a leaking motor housing exists. However, with today's medium to high voltage electric motors there is a further risk with compromised sealing in that the water may be electrified and serious risk of electrical shocks is introduced. This may occur if the electrical sealing of the power cables from a power supply to an immersed electrical motor is damaged such that a part of the motor in direct contact with water carries the supply voltage.

Therefore, there is a large need for an improved solution for electric leakage safety for an immersible electrical motor.

### SUMMARY

An object of the present disclosure is to provide a method for electric leakage of an electric motor immersed in water which seeks to mitigate, alleviate, or eliminate one or more of the above-identified deficiencies in the art and disadvantages singly or in any combination and to provide an improved method and a protection system.

The present inventors have found that a compromised electric isolation of an immersed electric motor may be detected by means of a sensor assembly that is configured to measure an electrical potential in the water and a control unit that is configured to disconnect the power supply from the electric motor when the measured electric potential is equal to or larger than a threshold value.

By exploiting these finding, the inventors have devised a method and protection system.

The present invention provides a method for electric leakage safety of an electric motor immersed in water and being connected to a power supply, wherein the method uses a protection system, wherein the protection system comprises a sensor arrangement operable to measure an electrical potential in the water surrounding the immersed electric motor and to output a sensor signal comprising information about the measured electrical potential, a control unit operable to receive said sensor signal, wherein the control unit is further operable to control the power supply connected to the electric motor by means of a control signal. The method comprising connecting the power supply to the electric motor, measuring with the sensor arrangement the electrical potential, and disconnecting the power supply from the immersed electric motor by means of said control signal when the electric potential is above, or equal to, a threshold value indicative of an electric leakage.

According to one embodiment, the threshold value is based on historical sensor signals. This allows adaption to different types of water conductivity and sensor arrangements.

According to one embodiment, the step of connecting the power supply to the electric motor comprises connecting the electric motor to the power supply during a first period of time.

According to one embodiment, the first period of time corresponds to a duty cycle smaller than 1%. This provides an increased safety since the power supply is connected only a small fraction of time to the electric motor, which reduces risk for damages and accidents.

According to one embodiment, the first period of time is smaller than 100 us. This further decreases the risk for damages and accidents.

According to one embodiment, the method comprises providing the sensor arrangement electrically isolated from the electric motor at distance smaller than 20 cm.

According to one embodiment, the distance is smaller than 10 cm.

According to one embodiment, the distance is smaller than 5 cm.

The present invention also provides a protection system for electric leakage safety of an electric motor immersed in water and being connected to a power supply. The protection system comprises a sensor arrangement operable to measure an electrical potential in the water surrounding the immersed electric motor and to output a sensor signal comprising information about the measured electrical potential. The protection system further comprises a control unit operable to receive said sensor signal. The control unit is further operable to control the power supply connected to the electric motor by means of a control signal. The control unit is operable to generate a control signal that causes a connection of the power supply to the electric motor, and measure with the sensor arrangement the electrical potential and when the measured electric potential is above, or equal to, a threshold value generate a control signal that disconnects the power supply from the immersed electric motor.

According to one embodiment, the threshold value is based on historical sensor signals.

According to one embodiment, the connection of the power supply to the electric motor comprises a connection of the electric motor to the power supply during a first period of time.

According to one embodiment, the first period of time corresponds to a duty cycle smaller than 1%.

According to one embodiment, the first period of time is smaller than 100 us.

According to one embodiment, the sensor arrangement is electrically isolated from the electric motor at distance smaller than 20 cm from the electric motor.

According to one embodiment, the distance is smaller than 10 cm.

According to one embodiment, the distance is smaller than 5 cm.

The present invention also provides a boat comprising an immersible electric motor, a power supply for powering the immersible electric motor. The boat further comprises a protection system according to embodiments disclosed herein.

Further objects and advantages may be found in the detailed description.

### BRIEF DESCRIPTION OF THE DRAWINGS

The foregoing will be apparent from the following more particular description of the example embodiments, as illustrated in the accompanying drawings in which like reference characters refer to the same parts throughout the different views. The drawings are not necessarily to scale, emphasis instead being placed upon illustrating the example embodiments.

FIG. 1 is a schematic block drawing of an immersible electric motor and a protection system according to embodiments of the present invention.

FIG. 2 is a flow chart illustrating embodiments of method steps.

FIG. 3 is a voltage vs. time diagram according to an embodiment.

FIG. 4 is a schematic drawing of a sensor arrangement according to an embodiment.

FIG. 5 is a schematic drawing of a boat according to an embodiment.

### DETAILED DESCRIPTION

Aspects of the present disclosure will be described more fully hereinafter with reference to the accompanying drawings. The apparatus and method disclosed herein can, however, be realized in many different forms and should not be construed as being limited to the aspects set forth herein. Like numbers in the drawings refer to like elements throughout.

The terminology used herein is for the purpose of describing particular aspects of the disclosure only, and is not intended to limit the invention. As used herein, the singular forms “a”, “an” and “the” are intended to include the plural forms as well, unless the context clearly indicates otherwise.

In this disclosure the term disconnect is used to describe that a low resistance path is replaced with a high resistance path. In some embodiments, this means that an electrical connection is physically interrupted, for example by means of a relay. In some embodiments, this means that if a solid-state device is present in the current path the solid state device enters a high resistance mode upon receiving a control signal that indicates a disconnection. The solid-state device may for example be IGBT or MOSFET components.

Some of the example embodiments presented herein are directed towards a method for electric leakage safety of an electric motor immersed in water and being connected to a power supply. As part of the development of the example embodiments presented herein, a problem will first be identified and discussed.

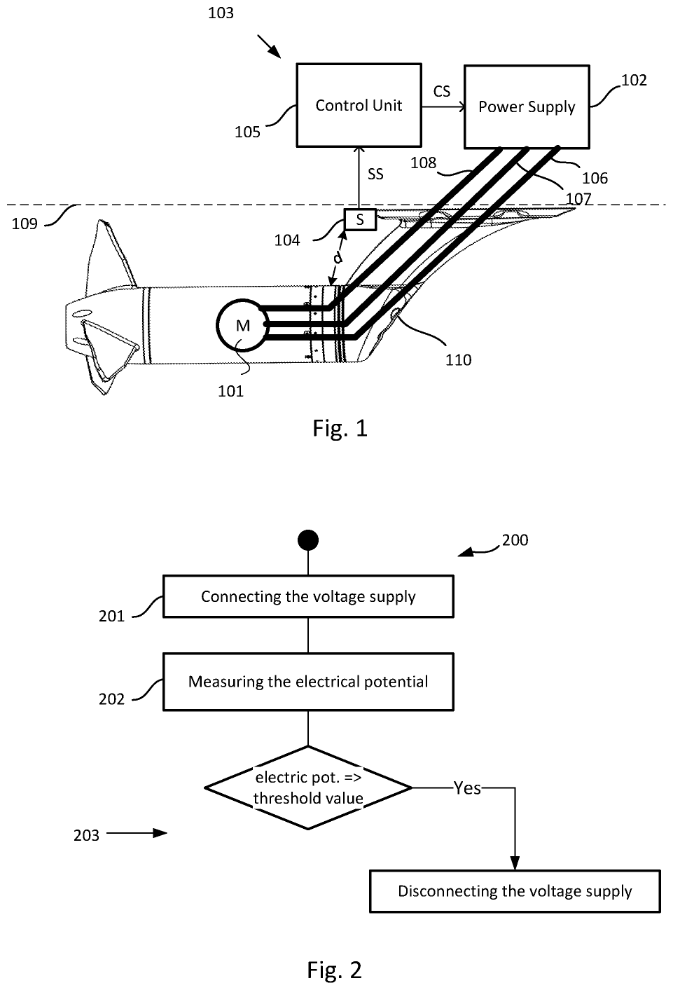

If one of the power lines 106-108 in FIG. 1 is damaged and the wires of the power line comes in contact with a part of the electric motor being in contact with the surrounding water. The water may be electrified and the standard housing leakage tests fails to indicate an error since no water enters the interior of the electric motor.

The known solutions fails to detect such an electric leakage.

The present inventors realized that such an electric leakage might be detected by measuring the electrostatic potential of a sensor arrangement arranged at a distance from the electric motor.

Now with reference made to FIG. 1 in which a protection system, generally designated 103, is illustrated. The protection system for electric leakage safety of an electric motor 101 is immersed in water and being connected to a power supply 102. The protection system 103 comprises a sensor arrangement 104 operable to measure an electrical potential in the water surrounding the immersed electric motor 101 and to output a sensor signal SS comprising information about the measured electrical potential.

In FIG. 1, the water level is indicated with a dashed line 109. The electric motor 101 is connected to a motor mount 110, which is configured to extend from a hull of a boat to the electric motor.

The protection system 103 further comprises a control unit 105 operable to receive said sensor signal SS. The control unit 105 is further operable to control the power supply 102 connected to the electric motor 101 by means of a control signal CS, the control unit 105 is operable to generate a control signal CS that causes a connection of the power supply 102 to the electric motor 101, and measure with the sensor arrangement 104 the electrical potential and when the measured electric potential is above, or equal to, a threshold value generate a control signal CS that disconnects the power supply 102 from the immersed electric motor 101.

The power supply 102 may in one embodiment comprise a battery pack and a voltage converter. The voltage converter is operable to receive the control signal and to convert the voltage of the battery pack to the desired voltage for the electric motor 101. The voltage converter may also be configured to generate a desired 3-phase signal for driving a permanent magnet motor.

Optionally, the threshold value is based on historical sensor signals.

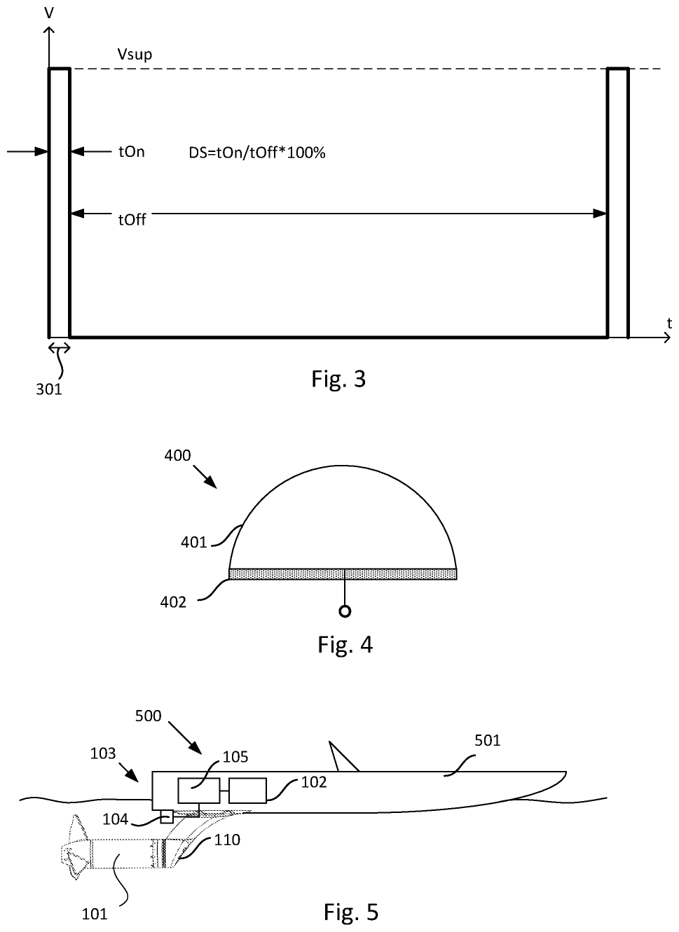

Now, reference is made to FIG. 3 in which a voltage vs time diagram is depicted. This diagram shows that the connection of the power supply to the electric motor comprises a connection of the electric motor to the power supply during a first period of time tOn.

The first period of time tOn corresponds to a duty cycle smaller than 1%. This reduces the risk of permanent damage to the motor if an electrical leakage error is present. The duty cycle is defined as tOn/tOff*100% as shown in the figure.

The risk for damage is further reduced if the first period of time tOn is smaller than 100 us.

The sensor arrangement 104 is electrically isolated from the electric motor at distance d smaller than 20 cm from the electric motor 101.

In one embodiment, the distance d is smaller than 10 cm and in one embodiment; the distance d is smaller than 5 cm.

In FIG. 1, the sensor arrangement 104 is arranged on the motor mount 110 at the distance d from the electric motor 101 as indicated in the figure. The sensor arrangement 104 is mounted electrically isolated from the conductive parts of the electric motor 101.

The sensor arrangement may comprise a sensor unit, where the sensor unit may be an electrode. The electrode may be immersed in the liquid also surrounding the electrical motor. The sensor unit may comprise a metal, for example brass, titan, stainless steel, steel, and aluminum or similar.

In FIG. 2, a method, generally designated 200, for electric leakage safety of an electric motor 101 immersed in water and being connected to a power supply 102 is illustrated as a flow diagram.

The method 200 uses a protection system 103. The protection system 103 comprises a sensor arrangement 104 operable to measure an electrical potential in the water surrounding the immersed electric motor and to output a sensor signal SS comprising information about the measured electrical potential.

The protection system further comprises a control unit 105 operable to receive said sensor signal SS, wherein the control unit 105 is further operable to control the power supply 102 connected to the electric motor 101 by means of a control signal CS.

The method 200 comprises:

Connecting 201 the power supply to the electric motor 101.

Measuring 202 with the sensor arrangement 104 the electrical potential.

Disconnecting 203 the power supply 102 from the immersed electric motor 101 by means of said control signal CS when the electric potential is above, or equal to, a threshold value indicative of an electric leakage.

In FIG. 4, an embodiment of a sensor arrangement 400 is illustrated. The sensor arrangement comprises a semi-spherical sensor surface 401 of a metallic material with low resistance and an isolator 402, which is configured to isolate the surface from the mounting surface. The sensor arrangement further comprises a terminal for connection of the sensor surface to the control unit.

In FIG. 5, a schematic boat 500 is illustrated. The boat 500 comprises an immersible electric motor 101, a power supply 102 for powering the immersible electric motor, and a protection system 103 according to embodiments disclosed herein.

An example scenario will now be described with reference made to FIG. 5. The immersed electric motor 101 being operatively connected to a hull 501 of the schematic boat 500 via a motor mount 110. The sensor arrangement 104 of the protection system 103 is also arranged on the hull of the boat. Assume that one of the power cables that extends from the power supply 102 to the electric motor 101 has a damaged isolation, such that a part of the motor is in electric contact with the leads of the damaged power cable. This means that it is possible that an external part of the motor carries the same electric potential as the leads of the damaged power cable. This poses an increased risk for both injuries and damages, especially if the electric motor is a high voltage motor, or a medium voltage motor. In this exemplary scenario, the boat is equipped with a protection system according to embodiments disclosed herein. This means that when the captain of the boat wants to engage the electric motor, the protection system will provide a control signal that causes pulses with a duty cycle less than 1% to be provided from the power supply to the electric motor 101. The sensor arrangement will detect and measure an increased electric potential due to the damaged power cable and if the measured electric potential is above a threshold value, the control unit will generate a control signal that causes the power supply to disconnect the immersed electric motor 101 from the power supply.

This way an increased safety is achieved since the immersed electric motor 101 is disconnected from the power supply.

In the drawings and specification, there have been disclosed exemplary embodiments. However, many variations and modifications can be made to these embodiments. Accordingly, although specific terms are employed, they are used in a generic and descriptive sense only and not for purposes of limitation, the scope of the embodiments being defined by the following claims.

The description of the example embodiments provided herein have been presented for purposes of illustration. The description is not intended to be exhaustive or to limit example embodiments to the precise form disclosed, and modifications and variations are possible in light of the above teachings or may be acquired from practice of various alternatives to the provided embodiments. The examples discussed herein were chosen and described in order to explain the principles and the nature of various example embodiments and its practical application to enable one skilled in the art to utilize the example embodiments in various manners and with various modifications as are suited to the particular use contemplated. The features of the embodiments described herein may be combined in all possible combinations of methods, apparatus, modules, systems, and computer program products.

It should be appreciated that the example embodiments presented herein may be practiced in any combination with each other. It should be noted that the word “comprising” does not necessarily exclude the presence of other elements or steps than those listed and the words “a” or “an” preceding an element do not exclude the presence of a plurality of such elements. It should further be noted that any reference signs do not limit the scope of the claims, that the example embodiments may be implemented at least in part by means of both hardware and software, and that several “means”, “units” or “devices” may be represented by the same item of hardware.

In the drawings and specification, there have been disclosed exemplary embodiments. However, many variations and modifications can be made to these embodiments. Accordingly, although specific terms are employed, they are used in a generic and descriptive sense only and not for purposes of limitation, the scope of the embodiments being defined by the following claims.

1. A method for electric leakage safety of an electric motor immersed in water and being connected to a power supply, wherein the method uses a protection system, wherein the protection system comprises:
a sensor arrangement operable to measure an electrical potential in the water surrounding the immersed electric motor and to output a sensor signal (SS) comprising information about the measured electrical potential;
a control unit operable to receive said sensor signal (SS), wherein the control unit is further operable to control the power supply connected to the electric motor by means of a control signal (CS);
the method comprising:
connecting the power supply to the electric motor;
measuring with the sensor arrangement the electrical potential;
disconnecting the power supply from the immersed electric motor by means of said control signal (CS) when the electric potential is above, or equal to, a threshold value indicative of an electric leakage.

2. A method according to claim 1, wherein the threshold value is based on historical sensor signals.

3. A method according to claim 1, wherein the step of connecting the power supply to the electric motor comprises:
connecting the electric motor to the power supply during a first period of time (tOn).

4. A method according to claim 3, wherein the first period of time (tOn) corresponds to a duty cycle smaller than 1%.

5. A method according to claim 3, wherein the first period of time (tOn) is smaller than 100 us.

6. A method according to claim 5, further comprises:
providing the sensor arrangement electrically isolated from the electric motor at distance (d) smaller than 20 cm.

7. A method according to claim 6, wherein the distance (d) is smaller than 10 cm.

8. A method according to claim 7, wherein the distance (d) is smaller than 5 cm.

9. A protection system for electric leakage safety of an electric motor immersed in water and being connected to a power supply, wherein the protection system comprises:
a sensor arrangement operable to measure an electrical potential in the water surrounding the immersed electric motor and to output a sensor signal (SS) comprising information about the measured electrical potential;
a control unit operable to receive said sensor signal (SS), wherein the control unit (105) is further operable to control the power supply connected to the electric motor by means of a control signal (CS), the control unit is operable to generate a control signal (CS) that causes a connection of the power supply to the electric motor, and measure with the sensor arrangement the electrical potential and when the measured electric potential is above, or equal to, a threshold value generate a control signal (CS) that disconnects the power supply from the immersed electric motor.

10. A protection system according to claim 9, wherein the threshold value is based on historical sensor signals.

11. A protection system according to any one of claim 9, wherein the connection of the power supply to the electric motor comprises a connection of the electric motor to the power supply during a first period of time (tOn).

12. A protection system according to claim 11, wherein the first period of time (tOn) corresponds to a duty cycle smaller than 1%.

13. A protection system according to claim 11, wherein the first period of time (tOn) is smaller than 100 us.

14. A protection system according to claim 9, wherein the sensor arrangement is electrically isolated from the electric motor at distance (d) smaller than 20 cm from the electric motor.

15. A protection system according to claim 14, wherein the distance (d) is smaller than 10 cm.

16. A protection system according to claim 15, wherein the distance (d) is smaller than 5 cm.

17. A boat comprising:
an immersible electric motor;
a power supply for powering the immersible electric motor; and
a protection system according to claim 9.
